(19) United States
(12) Patent Application Publication
(10) Pub. No.: US 2007/0099422 A1
(43) Pub. Date: May 3, 2007

(54) Process for electroless copper deposition

(76) Inventors: Kapila Wijekoon, Palo Alto, CA (US); Timothy W. Weidman, Sunnyvale, CA (US); Arulkumar Shanmugasundram, Sunnyvale, CA (US)

Correspondence Address: PATTERSON & SHERIDAN, LLP, 3040 POST OAK BOULEVARD, SUITE 1500, HOUSTON, TX, 77056, US

(21) Appl. No.: 11/261,409

(22) Filed: Oct. 28, 2005

(51) Int. Cl. H01L 21/44

(52) U.S. Cl. 438/687

(57) ABSTRACT

Embodiments of the invention provide a method for depositing a copper material on a substrate by an electroless deposition process and also provide a composition of an electroless deposition solution. In one embodiment, the copper material is deposited from an electroless copper solution that contains an additive, such as an inhibitor, to promote a bottom-up fill process. In one aspect, the field of the substrate may be maintained free of copper material or substantially free of copper material during the electroless deposition process. Prior to the electroless deposition process for forming the copper material, a barrier layer may be deposited on the substrate, and thereafter, a ruthenium layer may be deposited thereon. In one example, the copper material is formed during a bottom-up, electroless deposition process directly on the ruthenium layer. Alternatively, a seed layer may be formed on the ruthenium layer prior to depositing the copper material.

### BACKGROUND OF THE INVENTION

1. Field of the Invention

Embodiments of the invention generally relate to a method for depositing materials on a substrate, and more particularly to methods for forming a copper material on a substrate surface by an electroless deposition process.

2. Description of the Related Art

Multilevel metallization for nodes of 45 nm, 32 nm or smaller is an important technology for the next generation of very large scale integration (VLSI). The multilevel interconnects that lie at the heart of this technology include high aspect ratio features, such as contacts, vias, lines and other apertures. Reliable formation of these features is important for the success of VLSI and the continued effort to increase quality and circuit density on individual substrates. Therefore, there is a great amount of ongoing effort being directed to the formation of void-free features having high aspect ratios of 10:1 (height:width) or greater.

Copper is a choice metal for filling VLSI features, such as a high aspect ratio contact (HARC) and other sub-micron interconnect features. Contacts are formed by depositing a conductive interconnect material, such as copper into an opening (e.g., via) on the surface of insulating material disposed between two spaced-apart conductive layers. The high aspect ratio of such an opening may inhibit deposition of the conductive interconnect material that demonstrates satisfactory step coverage and gap-fill. Copper as an interconnect material within a HARC may form of voids or seams. Although copper is a popular interconnect material, devices containing copper materials may also suffer since copper by diffuse into neighboring layers, such as dielectric layers. The resulting and undesirable presence of copper causes dielectric layers to become conductive and electronic devices to fail. Therefore, barrier materials are used to control copper diffusion by depositing a barrier layer between the copper layer and the dielectric layer.

A typical sequence for forming an interconnect includes depositing one or more non-conductive layers, etching at least one of the layers to form one or more features therein, depositing a barrier layer in the feature and depositing one or more conductive layers, such as copper, to fill the feature. The barrier layer typically includes a refractory metal nitride and/or silicide, such as titanium or tantalum. Of this group, tantalum nitride is one of the most desirable materials for use as a barrier layer. Tantalum nitride has one of the lowest electrical resistivities of the metal nitrides and is also a good barrier to prevent copper diffusion, even when relatively thin layers are formed (e.g., about 20 Å or less). A tantalum nitride layer is typically deposited by conventional deposition techniques, such as physical vapor deposition (PVD), atomic layer deposition (ALD) or chemical vapor deposition (CVD).

Tantalum nitride does have some negative characteristics, which include poor adhesion to the copper layer deposited thereon. Poor adhesion of the subsequently deposited copper layers can lead to poor electromigration in the formed device and possibly cause process contamination issues in subsequent processing steps, such as during a chemical mechanical polishing (CMP) process. A tantalum nitride layer exposed to oxygen sources or other contaminants may cause the exposed surface of the tantalum nitride layer to oxidize thus preventing the formation of a strong bond to the subsequently deposited copper layer. The interface between a tantalum nitride barrier layer and a copper layer is likely to separate during a standard tape test.

Therefore, a need exists for a method to deposit a copper-containing layer on a barrier layer with good step coverage, strong adhesion, low electrical resistance and no seams or voids within a high aspect ratio interconnect feature.

### SUMMARY OF THE INVENTION

In one embodiment, a method for forming a copper-containing material on a substrate is provided which includes forming a barrier layer on a substrate, forming a ruthenium material on the barrier layer and exposing the substrate to an electroless copper solution containing an inhibitor source to form a copper material on the ruthenium material. In some embodiments, the copper material is deposited as a seed layer and a copper bulk layer is deposited thereon. For example, the copper bulk layer may be deposited by an electroless deposition process or an electrochemical plating (ECP) process. In other embodiments, the copper material is deposited directly over the ruthenium material as a bulk layer during an electroless deposition process. In one embodiment, a substrate contains apertures that are filled with the copper material free or substantially free of voids or seams during a bottom-up fill process. In some examples, the substrate field is free or substantially free of the copper material during and after an electroless deposition process.

The method further provides that the barrier layer may be deposited to a thickness of about 20 Å or less by an ALD process or a PVD process. The barrier layer contains a barrier material that includes tantalum, tantalum nitride, tantalum silicon nitride, titanium, titanium nitride, titanium silicon nitride, tungsten nitride, alloys thereof, derivatives thereof or a combination thereof. Also, the ruthenium material may be deposited to a thickness of about 20 Å or less by an ALD process or a PVD process. Preferably, the barrier layer and the ruthenium material may be deposited each to a thickness of about 10 Å or less by an ALD process. Thereafter, the substrate may be exposed to an annealing process, such as a thermal annealing process, for reducing or removing oxides and contaminants from the surface of the ruthenium material. In another embodiment, a seed layer may be deposited on the ruthenium layer prior to depositing the copper material by the electroless deposition process. For example, the seed layer may contain copper and is formed by an electroless deposition process, an ECP process or a PVD process.

In another embodiment, a composition of an electroless copper solution is provided which includes various additives for controlling the formation of the copper material. In general, examples of the electroless solution may contain a copper source at a concentration within a range from about 10 mM to about 40 mM, a complexing agent source at a concentration within a range from about 75 mM to about 400 mM, a reductant source at a concentration within a range from about 100 mM to about 400 mM, an inhibitor source at a concentration within a range from about 10 ppm to about 100 ppm and a pH adjusting agent at a concentration to provide a pH value of at least about 10.

In one example, the electroless copper solution contains a copper source at a concentration within a range from about 10 mM to about 40 mM, an EDTA source at a concentration within a range from about 75 mM to about 400 mM, a glyoxylic acid source at a concentration within a range from about 100 mM to about 400 mM, a dipyridyl source at a concentration within a range from about 10 ppm to about 100 ppm, a surfactant source (e.g., polyethylene glycol (PEG) or polypropylene glycol (PPG)) at a concentration of about 1,000 ppm or less or within a range from about 0.1 g/L to about 1.0 g/L and a pH adjusting agent at a concentration to provide a pH value of at least about 11. In another example, the electroless solution may contain the copper source at a concentration of about 26 mM, the EDTA source at a concentration of about 205 mM, the glyoxylic acid source at a concentration of about 217 mM, the dipyridyl source at a concentration of about 25 ppm, the surfactant source at a concentration of about 0.5 g/L and the pH adjusting agent at a concentration to provide a pH value of at least about 12.

In another embodiment, the electroless copper solution is formed by an in-line mixing process and is exposed to the substrate surface at the point-of-use. In one example, a copper concentrate solution, a reductant concentrate solution and water may be combined during the in-line mixing process to form the electroless copper solution. The copper concentrate solution and the reductant concentrate solution may each contain an equal concentration or substantially equal concentrations of at least one complexing agent, such as an EDTA source.

In another embodiment, a method for forming a copper-containing material on a substrate is provided which includes depositing a ruthenium tantalum alloy on a substrate during a first deposition process and exposing the substrate to an electroless copper solution to form a copper material on the ruthenium tantalum alloy. The copper material may be formed as a seed layer or a bulk layer. In one example, a seed layer is deposited on the ruthenium tantalum alloy prior to the formation of the copper material. The ruthenium tantalum alloy may be deposited by an ALD process, but preferably is deposited by a PVD process. In one example, the ruthenium tantalum alloy contains about 50 wt % ruthenium and about 50 wt % tantalum. In other examples, the ruthenium tantalum alloy may contain more ruthenium or more tantalum. The ruthenium tantalum alloy may be deposited to a thickness of about 20 Å, preferably, about 10 Å or less.

In another embodiment, a method for forming a copper-containing material on a substrate is provided which includes forming a barrier layer on a substrate having at least one aperture, forming a ruthenium material on the barrier layer and filling the at least one aperture substantially free of voids and seams with a copper material during an electroless deposition process. In one example, a copper seed layer is deposited on the ruthenium material prior to filling the at least one aperture. The copper seed layer may deposited by a copper electroless deposition process or a PVD process. Usually, the at least one aperture is filled by a bottom-up manner during an electroless deposition process.

In another embodiment, a method for forming a copper-containing material on a substrate is provided that includes forming a barrier layer having a thickness of about 20 Å or less on a substrate during an ALD process or a PVD process, forming a ruthenium layer having a thickness of about 20 Å or less on the barrier layer during an ALD process or PVD process and exposing the substrate to an electroless copper solution to form a copper material on the ruthenium layer. In one example, the barrier layer contains a tantalum nitride layer deposited on a tantalum layer.

In another embodiment, a method for forming a copper-containing material on a substrate is provided that includes depositing a ruthenium material on a barrier layer disposed on a substrate, combining at least a copper concentrate solution and water by an in-line mixing step to form an electroless copper solution and exposing the substrate to the electroless copper solution to form a copper material on the ruthenium material. In one example, a reductant concentrate solution is also combined with the copper concentrate solution and the water during the in-line mixing step to form the electroless copper solution. In another example, the copper concentrate solution and the reductant concentrate solution each contain equal or substantially equal concentrations of a complexing agent.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1F illustrate schematic cross-sectional views of a substrate during various integrated circuit fabrication processes as described by embodiments herein.

### DETAILED DESCRIPTION OF THE PREFERRED EMBODIMENT

Embodiments of the invention provide a method for depositing copper material on a substrate by an electroless deposition process. In one embodiment, the copper material is deposited from an electroless copper solution that contains additives, such as an inhibitor, to promote a bottom-up fill process. In one example, the field of the substrate may be maintained free of copper material or substantially free of copper material during the electroless deposition process. Embodiments of the invention also provide a composition of the electroless copper solution. Generally, the electroless copper solution may contain a copper source (e.g., copper sulfate) at a concentration within a range from about 10 mM to about 40 mM, a complexing agent source (e.g., EDTA) at a concentration within a range from about 75 mM to about 400 mM, a reductant source (e.g., glycolic acid) at a concentration within a range from about 100 mM to about 400 mM, an inhibitor source (e.g., dipyridyl) at a concentration within a range from about 10 ppm to about 100 ppm, a surfactant source (e.g., PEG or PPG) at a concentration of about 1,000 ppm or less and a pH adjusting agent (e.g., TMAH) at a concentration to provide a pH value of at least about 10.

Prior to an electroless deposition process for depositing a copper material, a barrier layer is deposited on the substrate, and thereafter, a ruthenium layer is deposited thereon, as described by an embodiment herein. The barrier layer and the ruthenium layer may be deposited on the substrate by various vapor deposition processes, such as atomic layer deposition (ALD), plasma-enhanced ALD (PE-ALD) or physical vapor deposition (PVD). In one example, the copper material is formed during a bottom-up, electroless deposition process directly on the ruthenium layer. Alternatively, a seed layer may be formed on the ruthenium layer prior to depositing the copper material. The seed layer may contain copper and be deposited by an electroless deposition process, a PVD process or an electrochemical plating (ECP) process. In an alternative embodiment, a copper material may be formed directly on the ruthenium layer or on the seed layer by an ECP process.

Formation of Copper Interconnects

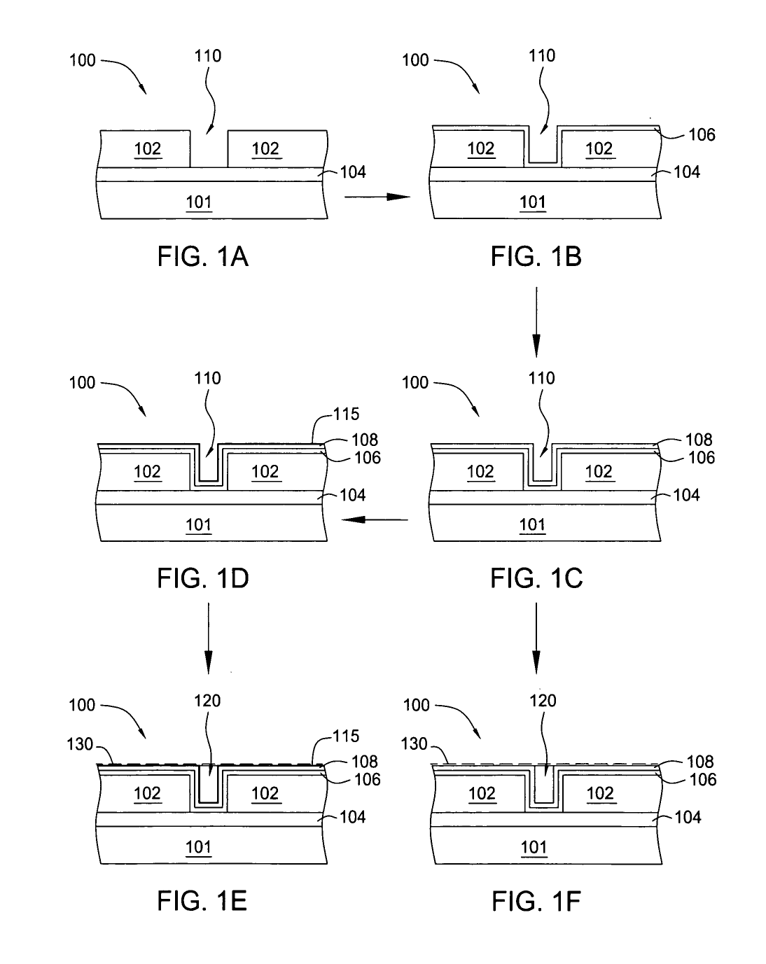

FIGS. 1A-1F illustrate cross-sectional views of substrate 100 at different stages of several interconnect fabrication sequences incorporating some of the embodiments described herein. FIG. 1A illustrates a cross-sectional view of substrate 100 having metal contact 104 and dielectric layer 102 disposed on layer 101. Layer 101 may contain a semiconductor material, such as silicon, germanium, silicon germanium, silicon carbide, silicon germanium carbide, gallium arsenide, derivatives thereof or combinations thereof. Layer 101 may be a surface of a deposited material or an underlying substrate, such as a wafer. Dielectric layer 102 may contain an insulating material such as, silicon oxide, silicon nitride, silicon oxynitride, carbon-doped silicon oxides, such as SiOXC_{y}, for example, BLACK DIAMOND™ low-k dielectric materials, available from Applied Materials, Inc., located in Santa Clara, California or other materials, such as SILK™, available from Dow Chemical Company. Also, dielectric layer 102 may contain a low-k dielectric material that includes an aerogel, such as ELK™, available from Schumacher, Inc. In some examples, dielectric layer 102 may contain high-k materials used in metal gate application, such as aluminum oxide, hafnium oxide, hafnium silicate, tantalum oxide, titanium oxide, titanium silicide, titanium silicate, boron strontium titanate, zirconium oxide, zirconium silicate, nickel silicide, cobalt silicide, silicates thereof, aluminates thereof, derivatives thereof or combinations thereof. Metal contact 104 may contain copper, aluminum, tungsten, silver or an alloy thereof. Aperture 110 may be defined in dielectric layer 102 to provide an opening to expose metal contact 104. Aperture 110 may be defined in dielectric layer 102 using conventional lithography and etching techniques. Although FIGS. 1A-1F illustrate substrate 100 containing only one opening by aperture 110, substrates actually contain multiple openings across the substrate surface.

Substrate 100 containing dielectric layer 102 may be exposed to a degassing process within a process chamber prior to depositing barrier layer 106. The degassing process may occur for a time period of about 5 minutes or less, for example, about 1 minute, while heating substrate 100 to a temperature within a range from about 250° C. to about 400° C., for example, about 350° C. The degassing process may further include maintaining the process chamber at a pressure within a range from about 1×10⁻⁷ Torr to about 1×10⁻⁵ Torr, for example, about 5×10⁻⁶ Torr. The degassing process removes volatile surface contaminates, such as water vapor, solvents or volatile organic compounds from substrate 100.

Barrier layer 106 is deposited on substrate 100 and may be used to prohibit or minimize copper diffusion into dielectric layer 102 (FIG. 1B). Barrier layer 106 may be formed over dielectric layer 102 and within aperture 110 and may include one or more metal-containing layers used as a copper-barrier material such as, for example, tantalum, tantalum nitride, tantalum silicon nitride, titanium, titanium nitride, titanium silicon nitride, tungsten, tungsten nitride, alloys thereof, derivatives thereof or combinations thereof. Barrier layer 106 may be formed by an ALD process, a PE-ALD process, a CVD process, a PE-CVD process, a PVD process or another suitable deposition process. The thickness of barrier layer 106 is usually less than about 100 Å, preferably, less than about 50 Å, and more preferably, less than about 30 Å, such as, within a range from about 2 Å to about 30 Å, preferably, from about 5 Å to about 25 Å, and more preferably, from about 10 Å to about 20 Å. Barrier layer 106 may be a discontinuous layer across dielectric layer 102, but preferably, barrier layer 106 is a continuous layer.

In one example, tantalum nitride may be formed by sequentially exposing substrate 100 to pentakis(dimethylamino) tantalum (PDMAT) and ammonia during an ALD process or a PE-ALD process. In another example, tantalum nitride may be formed by a PVD process. In one embodiment, a tantalum layer and a tantalum nitride layer are deposited separately or together as barrier layer 106 by ALD or PVD processes, as described in commonly assigned U.S. Pat. No. 6,951,804, which is incorporated herein in its entirety by reference. For example, a tantalum layer may be deposited by a PVD process and a tantalum nitride layer may be deposited by an ALD process on the tantalum layer to form barrier layer 106. In another example, a tantalum layer may be deposited by an ALD process and a tantalum nitride layer may be deposited by an ALD process on the tantalum layer to form barrier layer 106.

Ruthenium layer 108 is deposited on substrate 100 and may be used as a copper barrier material, an adhesion layer, a nucleation/seed layer or a catalytic surface layer. Ruthenium layer 108 may be formed on barrier layer 106 by a PVD process, but preferably, by an ALD process (FIG. 1C). The thickness of ruthenium layer 108 is variable depending on the fabricated device structure and geometry. Typically, the thickness of ruthenium layer 108 is less than about 100 Å, preferably, less than about 50 Å, and more preferably, less than about 30 Å, such as within a range from about 2 Å to about 30 Å, preferably, from about 5 Å to about 25 Å, and more preferably, from about 10 Å to about 20 Å. Ruthenium layer 108 may be a continuous layer or a discontinuous layer across barrier layer 106.

In one example, ruthenium layer 108 may be formed by sequentially exposing the substrate to a ruthenium precursor and reactant during an ALD process or a PE-ALD process. In another example, ruthenium layer 108 may be formed by a PVD process. In one embodiment, a ruthenium layer 108 may be deposited by an ALD process or a PE-PALD process as described in commonly assigned and co-pending U.S. Ser. No. 10/634,662, entitled “Ruthenium Layer Formation for Copper Film Deposition,” filed Aug. 4, 2003, and published as US 2004-0105934, U.S. Ser. No. 10/811,230, entitled “Ruthenium Layer Formation for Copper Film Deposition,” filed Mar. 26, 2004, and published as US 2004-0241321, and U.S. Ser. No. 60/714,580, filed Sep. 6, 2005 and entitled “Atomic Layer Deposition Process for Ruthenium Materials,” which are each incorporated herein in their entirety by reference. An ALD process chamber useful for depositing barrier layer 106 or ruthenium layer 108 is available from Applied Materials, Inc. and is described in commonly assigned U.S. Pat. Nos. 6,916,398, and 6,878,206, which are both incorporated herein by reference for describing ALD chambers and processes.

In another embodiment, instead of forming barrier layer 106 and ruthenium layer 108 as two distinct layers, a single layer (not shown) containing a tantalum ruthenium alloy may be deposited onto dielectric layer 102. The tantalum-ruthenium layer may be sputtered or deposited from the ruthenium tantalum alloy by a PVD process. In one example, barrier layer 106 may contain a ruthenium tantalum alloy containing about 50 wt % of ruthenium and about 50 wt % of tantalum. In alternative examples, the ruthenium tantalum alloy contains a ruthenium to tantalum ratio by weight of less than 1 or greater than 1. Therefore, in one example, the ruthenium tantalum alloy contains more ruthenium by weight, and in another example, the ruthenium tantalum alloy contains more tantalum by weight. The ruthenium tantalum alloy may be deposited as barrier layer 106 with a thickness of about 50 Å or less, preferably, about 20 Å or less, and more preferably, about 10 Å or less.

In an alternative embodiment, substrate 100 may be introduced to additional processes prior to depositing seed layer 115 or copper layer 120. Substrate 100 may be exposed to a thermal annealing process or a plasma annealing process. During a fabrication process, substrate 100 may be exposed to an oxidizer or other reagent to form an oxide layer or other contaminant on ruthenium layer 108. In one example, the oxide layer is formed within a process chamber during a cleaning process or another process that exposes substrate 100 to water, hydrogen peroxide, nitric acid or other oxidizing reagents. Alternatively, an oxide layer on ruthenium layer 108 may be formed outside of the process chamber due to water or oxygen exposure from the ambient air.

In either scenario, the oxide layer or contaminant may be removed or chemically reduced to form a metallic ruthenium surface of ruthenium layer 108 during an annealing process. Substrate 100 may be heated to a temperature within a range from about 100° C. to about 800° C., preferably, from about 200° C. to about 500° C., preferably, from about 250° C. to about 350° C., such as about 300° C. During the annealing process, substrate 100 may be exposed to hydrogen, nitrogen, forming gas, argon or combinations thereof. A thermal annealing process may last for a time period within a range from about 2 minutes to about 60 minutes, preferably, from about 5 minutes to about 30 minutes, and more preferably, from about 10 minutes to about 20 minutes. For example, substrate 100 may be heated to a temperature of about 290° C. for about 15 minutes while in an environment of hydrogen and nitrogen. In another example, substrate 100 may be exposed to a plasma, such as a reducing-plasma, for removing the oxide layer or contaminant while forming or revealing a metallic ruthenium surface on ruthenium layer 108. A plasma may include hydrogen, nitrogen, ammonia, forming gas, argon, helium or combinations thereof.

Thereafter, seed layer 115 may be formed on ruthenium layer 108 and aperture 110 may be filled with copper layer 120 in one embodiment described herein (FIGS. 1D-1E). In an alternative embodiment, aperture 110 may be “bottom-up” filled directly with copper layer 120 (FIG. 1F). Seed layer 115 may contain copper, tungsten, aluminum, platinum, palladium, silver or an alloy thereof. Seed layer 115 may be a formed on ruthenium layer 108 by an electroless deposition process, an ECP process, an ALD process or a PVD process. Preferably, seed layer 115 contains copper or a copper alloy and is deposited by an electroless deposition process or an ECP process. Seed layer 115 may be a continuous layer or a discontinuous layer across ruthenium layer 108. Usually, seed layer 115 is a discontinuous layer. The thickness of seed layer 115 may be less than about 500 Å, such as within a range from about 10 Å to about 250 Å, preferably, from about 50 Å to about 200 Å, and more preferably, about 100 Å.

Copper layer 120 may contain copper or a copper alloy formed by one or more suitable deposition processes (FIGS. 1E and 1F). Copper layer 120 may be deposited by an electroless deposition process, an ECP process or a CVD process. Preferably, copper layer 120 is formed by depositing a copper material during an electroless deposition process or an ECP process. In one embodiment, copper layer 120 is deposited over seed layer 115 (FIG. 1E) and in another embodiment, copper layer 120 is deposited directly over ruthenium layer 108 (FIG. 1F). In one example, copper layer 120 is deposited into aperture 110 while substrate field 130 remains bare or substantially bare of copper material during a bottom-up, electroless deposition process. In an alternative example, copper layer 120 is deposited into aperture 110 during a bottom-up, electroless deposition process while a layer of copper material is formed on substrate field 130 (not shown). Thereafter, the layer of copper material may be removed from substrate field 130 by a chemical mechanical polishing (CMP) process or an electro-CMP (ECMP) process.

In another embodiment, a predetermined concentration of at least one inhibitor source within the electroless copper solution may be selected to minimize or prevent copper material deposition on substrate field 130 during a bottom-up fill process. A “bottom-up” process or a “bottom-up” fill is used herein to describe the deposition or the formation of a metal on the bottom of an opening, a via or an aperture within a substrate and the continued process of depositing or forming the metal from the bottom of the aperture up to at least about the field of the substrate. Preferably, a bottom-up process forms no material or substantially no material on the side walls of the aperture prior to the metal filling the aperture. Therefore, the aperture may be filled containing no gaps or seams, or substantially no gaps or seams, within the deposited metal.

In one embodiment, an electroless deposition process to form copper materials (e.g., copper layer 120 or seed layer 115) may utilize a pre-mixed solution of an electroless copper solution. In another embodiment, an electroless deposition process to form copper materials (e.g., copper layer 120 or seed layer 115) may utilize an in-line mixing process to form the electroless copper solution. The in-line mixing process maybe used for point-of-use methods near the substrate surface during the deposition process. The in-line mixing process may contain the combination of two, three, four or more componential solutions to form an electroless copper solution. In one example, the electroless copper solution is formed by combining a buffered cleaning solution, a copper-containing solution, a reducing solution and water, where each solution may be a concentrate and water is added to reach a predetermined concentration of the final solution. In another example, the electroless copper solution is formed by combining a buffered cleaning solution, a copper-containing solution and a reducing solution, where each of the solutions are pre-diluted and therefore do not require additional water. In another example, the electroless copper solution is formed by combining a buffered copper-containing solution, a reducing solution and water, where a buffered cleaning solution and a copper-containing solution are combined to form the buffered copper-containing solution. Further details of in-line mixing processes and componential solutions for point-of-use methods are further described in the commonly assigned and co-pending U.S. Ser. No. 10/967,919, filed on Oct. 18, 2004, entitled “Selective Self-initiating Electroless Capping of Copper with Cobalt-containing Alloys,” and published as US 2005-0136193, which is incorporated by reference to the extent not inconsistent with the claimed aspects and description herein.

The electroless deposition process may be conducted at a temperature within a range from about 35° C. to about 120° C., preferably, from about 55° C. to about 85° C., and more preferably, from about 65° C. to about 75° C., such as about 70° C. Water used to form the electroless copper solution may be degassed, preheated and/or deionized water. Degassing the water reduces the oxygen concentration of the subsequently formed electroless copper solution. An electroless copper solution with a low oxygen concentration (e.g., less than about 100 ppm) may be used during the deposition process. Preheated water allows forming the electroless copper solution by an in-line mixing power at a predetermined temperature just below the temperature used to initiate the deposition process, thereby shortening the process time.

Electroless deposition processes for depositing materials described herein may be conducted within an electroless deposition process cell. Process cells that may be used are further described in commonly assigned and co-pending U.S. Ser. No. 10/965,220, filed on Oct. 14, 2004, entitled “Apparatus for Electroless Deposition,” and published as US 2005-0081785 and U.S. Ser. No. 10/996,342, filed on Nov. 22, 2004, entitled “Apparatus for Electroless Deposition of Metals on Semiconductor Wafers,” and published as US 2005-0160990, which are each incorporated by reference in their entirety to the extent not inconsistent with the claimed aspects and description herein.

Electroless Copper Solution

Copper and copper-containing alloys as described herein may be formed from an electroless copper solution as a copper layer (e.g., seed layer 115 or copper layer 120) during an electroless deposition process. In one example, the electroless copper solution generally contains a copper source, at least one complexing agent, a reductant, an inhibitor/suppressor, optional additives and a pH adjusting agent. In one example, the components of the electroless copper solution are dissolved within an aqueous solution having a basic pH, such as within a range from about 10 to about 13.

A copper source is contained within the electroless copper solution and provides dissolved copper ions (e.g., Cu²⁺ or Cu¹⁺) that may be reductively plated or deposited onto a surface as metallic copper. The copper source includes water soluble copper precursors, for example, copper sulfate (CuSO₄), copper chloride (CuCl₂), copper acetate ((CH₃CO₂)₂Cu), copper acetylacetonate ((C₅H₇O₂)₂Cu), derivatives thereof, hydrates thereof or combinations thereof. Some copper sources are commonly available as hydrate derivatives, such as CuSO₄·5H₂O, CuCl₂·2H₂O and (CH₃CO₂)₂Cu·H₂O. The electroless copper solution may have a copper source at a concentration within a range from about 5 mM to about 80 mM, preferably, from about 10 mM to about 40 mM, and more preferably, from about 20 mM to about 30 mM, such as about 26 mM. In one embodiment, copper sulfate is the preferred copper source within the electroless copper solution. In one example, the electroless copper solution contains about 26 mM of CuSO₄·5H₂O.

The electroless copper solution has at least one complexing agent or chelator to form complexes with the copper ions while providing stability and control during the deposition process. Complexing agents also provide buffering characteristics for the electroless copper solution. Complexing agents generally have functional groups, such as carboxylic acids, dicarboxylic acids, polycarboxylic acids, amino acids, amines, diamines or polyamines. Specific examples of useful complexing agents for the electroless copper solution include ethylene diamine tetraacetic acid (EDTA), ethylene diamine (EDA), citric acid, citrates, glyoxylates, glycine, amino acids, derivatives thereof, salts thereof or combinations thereof. The electroless copper solution may have a complexing agent at a concentration within a range from about 50 mM to about 500 mM, preferably, from about 75 mM to about 400 mM, and more preferably, from about 100 mM to about 300 mM, such as about 200 mM. In one embodiment, an EDTA source is the preferred complexing agent within the electroless copper solution. In one example, the electroless copper solution contains about 205 mM of an EDTA source. The EDTA source may include EDTA, ethylenediaminetetraacetate, salts thereof, derivatives thereof or combinations thereof.

The electroless copper solution contains at least one reductant. Reductants provide electrons to induce the chemical reduction of copper ions while forming and depositing the copper material, as described herein. Reductants include organic reductants (e.g., glyoxylic acid or formaldehyde), hydrazine, organic hydrazines (e.g., methyl hydrazine), hypophosphite sources (e.g., hypophosphorous acid (H₃PO₂), ammonium hypophosphite ((NH₄)₄₋ₓ H_{xPO}₂) or salts thereof), borane sources (e.g., dimethylamine borane complex ((CH₃)₂NH·BH₃), DMAB), trimethylamine borane complex ((CH₃)₃N·BH₃), TMAB), tert-butylamine borane complex (^{t}BuNH₂·BH₃), tetrahydrofuran borane complex (THF·BH₃), pyridine borane complex (C₅H₅N·BH₃), ammonia borane complex (NH₃·BH₃), borane (BH₃), diborane (B₂H₆), derivatives thereof, complexes thereof, hydrates thereof or combinations thereof. The electroless copper solution may have a reductant at a concentration within a range from about 20 mM to about 500 mM, preferably, from about 100 mM to about 400 mM, and more preferably, from about 150 mM to about 300 mM, such as about 220 mM. Preferably, an organic reductant or organic-containing reductant is utilized within the electroless copper solution, such as glyoxylic acid or a glyoxylic acid source. The glyoxylic acid source may include glyoxylic acid, glyoxylates, salts thereof, complexes thereof, derivatives thereof or combinations thereof. In a preferred example, glyoxylic acid monohydrate (HCOCO₂H·H₂O) is contained within the electroless copper solution at a concentration of about 217 mM.

Also, the electroless copper solution may have an inhibitor, a suppressor, a leveler, an accelerator or other additives. Inhibitors or suppressors may be used to suppress copper deposition by initially adsorbing onto underlying surfaces (e.g., substrate surface) and therefore blocking access to the surface. A predetermined concentration of an inhibitor or inhibitors within the electroless copper solution may be varied to control the amount of blocked underlying surfaces, and therefore, provides additional control of the copper material deposition (e.g., deposition rate) to promote a bottom-up fill process.

An electroless copper solution usually contains at least one inhibitor, if not more. Specific examples of useful inhibitors for the electroless copper solution include 2,2′-dipyridyl, dimethyl dipyridyl, polyethylene glycol (PEG), polypropylene glycol (PPG), polyoxyethylene-polyoxypropylene copolymer (POCP), benzotriazole (BTA), derivatives thereof or combinations thereof. The electroless copper solution may have an inhibitor at a concentration within a range from about 20 ppb to about 600 ppm, preferably, from about 100 ppb to about 200 ppm, and more preferably, from about 10 ppm to about 100 ppm. In one example, the polyoxyethylene-polyoxypropylene copolymer is used as a mixture of polyoxyethylene and polyoxypropylene at different weight ratios, such as 80:20, 50:50 or 20:80. In another example, a PEG-PPG solution may contain a mixture of PEG and PPG at different weight ratios, such as 80:20, 50:50 PATENT or 20:80. In one embodiment, PEG, PPG or 2,2′-dipyridyl may be used alone or in combination as a inhibitor source within the electroless copper solution. In one example, the electroless copper solution contains PEG or PPG at a concentration within a range from about 0.1 g/L to about 1.0 g/L, preferably, about 0.5 g/L. In another example, the electroless copper solution contains 2,2′-dipyridyl at a concentration within a range from about 10 ppm to about 100 ppm, preferably, about 25 ppm. In another example, the electroless copper solution contains PEG or PPG at a concentration within a range from about 0.1 g/L to about 1.0 g/L, preferably, about 0.5 g/L and also contains 2,2′-dipyridyl at a concentration within a range from about 10 ppm to about 100 ppm, preferably, about 25 ppm.

Levelers within the electroless copper solution are used to achieve different deposition thickness as a function of leveler concentration and feature geometry while depositing copper materials. The electroless copper solution may have a leveler at a concentration within a range from about 20 ppb to about 600 ppm, preferably, from about 100 ppb to about 100 ppm. Examples of levelers that may be employed in an electroless copper solution include, but are not limited to, alkylpolyimines and organic sulfonates, such as 1-(2-hydroxyethyl)-2-imidazolidinethione (HIT), 4-mercaptopyridine, 2-mercaptothiazoline, ethylene thiourea, thiourea or a derivative thereof.

The electroless copper solution may contain other additives to help accelerate the deposition process and achieve bottom-up fill. A brightener may be contained within the electroless copper solution as an additive to provide further control of the deposition process. The role of a brightener is to achieve a smooth surface of the deposited copper material. The electroless copper solution may have an additive (e.g., brightener) at a concentration within a range from about 20 ppb to about 600 ppm, preferably, from about 100 ppb to about 100 ppm. Additives that are useful within the electroless copper solution for depositing copper materials may include sulfur-based compounds such as bis(3-sulfopropyl) disulfide (SPS), 3-mercapto-1-propane sulfonic acid (MPSA), aminoethane sulfonic acids, thiourea, derivatives thereof or combinations thereof.

The electroless copper solution may also have a surfactant. The surfactant acts as a wetting agent to reduce the surface tension between the electroless copper solution and the substrate surface. The electroless copper solution generally contains a surfactant at a concentration of about 1,000 ppm or less, preferably, about 500 ppm or less, such as within a range from about 100 ppm to about 300 ppm. The surfactant may have ionic or non-ionic characteristics. A preferred surfactant includes glycol ether based surfactants, such as PEG, PPG or the like. Due to beneficial characteristics, PEG and PPG may be used as a surfactant, an inhibitor and/or a suppressor. In one example, a glycol ether based surfactant may contain polyoxyethylene units, such as TRITON® 100, available from Dow Chemical Company. Other surfactants that may be used within the electroless copper solution include dodecyl sulfates, such as sodium dodecyl sulfate (SDS). The surfactants may be single compounds or a mixture of compounds having molecules that contain varying lengths of hydrocarbon chains.

A pH adjusting agent, generally a base, is used to adjust the pH of the electroless copper solution to a value within a range from about 10 and about 13.5, preferably, from about 11 to about 13, and more preferably, from about 12.0 to about 12.7. Suitable pH adjusting agents include hydroxides, such as tetramethylammonium hydroxide ((CH₃)₄NOH; TMAH), ammonium hydroxide (NH₄OH), derivatives thereof or combinations thereof. In a preferred example, the electroless copper solution contains TMAH at a concentration to have a pH value within a range from about 12.0 to about 12.7.

In one example, an electroless copper solution contains copper sulfate pentahydrate at a concentration within a range from about 1 g/L to about 30 g/L, EDTA at a concentration within a range from about 10 g/L to about 300 g/L, glyoxylic acid monohydrate at a concentration within a range from about 5 g/L to about 50 g/L, PEG at a concentration within a range from about 0.1 g/L to about 2.0 g/L, 2,2′-dipyridyl at a concentration within a range from about 5 ppm to about 100 ppm, an amount of TMAH (25% solution) sufficient to adjust the pH to a value within a range from about 11.5 to about 13.0 and the balance of Dl water to adjust the volume to about 1 L.

In another example, an electroless copper solution contains copper sulfate pentahydrate at a concentration within a range from about 3 g/L to about 15 g/L, EDTA at a concentration within a range from about 30 g/L to about 120 g/L, glyoxylic acid monohydrate at a concentration within a range from about 10 g/L to about 30 g/L, PEG at a concentration within a range from about 0.3 g/L to about 0.7 g/L, 2,2′-dipyridyl at a concentration within a range from about 15 ppm to about 40 ppm, an amount of TMAH sufficient to adjust the pH to a value within a range from about 12.0 to about 13.0 and the balance of Dl water to adjust the volume to about 1 L.

In a specific example, an electroless copper solution contains about 6.5 g/L of copper sulfate pentahydrate, about 60 g/L of EDTA, about 20 g/L of glyoxylic acid monohydrate, about 0.5 g/L of PEG, about 25 ppm of 2,2′-dipyridyl, an amount of TMAH sufficient to adjust the pH to a value of about 12.7 and the balance of Dl water to adjust the volume to about 1 L.

In another embodiment, substrate 100 is exposed at the point-of-use to an in-line mixed electroless copper solution to form copper materials (e.g., copper layer 120 or seed layer 115). In one example, the electroless copper solution is formed by combining a complexing agent solution containing a complexing agent (e.g., an EDTA source), a copper-containing solution, a reducing solution containing a reductant (e.g., glycolic acid) and water, where each solution may be a concentrate and water is added to reach a predetermined concentration of the final solution. In another example, each of the solutions are pre-diluted and therefore do not require additional water. In one aspect, the complexing agent solution, the copper-containing solution and the reducing solution each contain at least one complexing agent, such that each solution may have the same of different complexing agent. Preferably, each solution has the same concentration of the complexing agent.

In another embodiment, the electroless copper solution is formed by in-line mixing a copper-containing solution, a reducing solution and water at the point-of-use during an electroless deposition process. In one example, the copper-containing solution contains a copper source and a complexing agent. In another example, the reducing solution contains a reductant and a complexing agent. In another example, the copper-containing solution and the reducing solution each contain at least one complexing agent, such as an EDTA source. Preferably, the copper-containing solution and the reducing solution each contain the complexing agent at an equal or substantially equal concentration. The copper-containing solution, the reducing solution and water are mixed at predetermined weight ratios to form the electroless copper solution. In one embodiment, the predetermined weight ratio of the copper-containing solution to the reducing solution to water may be about 0.5 to about 0.5 to about 9; about 1 to about 1 to about 8; about 0.5 to about 1.5 to about 8; about 1.5 to about 0.5 to about 8; about 1.5 to about 1.5 to about 7; about 1 to about 1 to about 3; about 2.5 to about 2.5 to about 5; about 2 to about 3 to about 5; about 3 to about 2 to about 5; about 3 to about 3 to about 4; or about 1 to about 1 to about 1.

In one example, the copper-containing solution, the reducing solution and water are mixed at a predetermined weight ratio to form an electroless copper solution that contains a copper source (e.g., copper sulfate) at a concentration within a range from about 10 mM to about 40 mM, a complexing agent source (e.g., an EDTA source) at a concentration within a range from about 75 mM to about 400 mM, a reductant source (e.g., glyoxylic acid monohydrate) at a concentration within a range from about 100 mM to about 400 mM, an inhibitor source (e.g., 2,2′-dipyridyl) at a concentration within a range from about 10 ppm to about 100 ppm, a surfactant source (e.g., PEG) at a concentration of about 1,000 ppm or less, an amount of a pH adjusting agent (e.g., 25% TMAH solution) sufficient to adjust the pH to a value within a range from about 11.5 to about 13.0.

### EXAMPLES OF INTEGRATION PROCESS

Several integration sequences may be conducted during Examples 1-17 for forming various interconnects on substrate 100 containing different permutations of barrier layer 106, ruthenium layer 108, seed layer 115 or copper layer 120.

### Example 1

The subsequent steps follow: a) deposition of a barrier layer (e.g., ALD or PVD of tantalum nitride); b) deposition of ruthenium layer by ALD or PVD; c) expose substrate to annealing process; d) deposition of seed copper by electroless, ECP or PVD; and e) deposition of bulk copper by electroless or ECP.

### Example 2

The subsequent steps follow: a) pre-clean of the substrate; b) deposition of a barrier layer (e.g., ALD or PVD of tantalum nitride); c) deposition of ruthenium layer by ALD or PVD; d) deposition of seed copper by electroless, ECP or PVD; and e) deposition of bulk copper by electroless or ECP.

### Example 3

The subsequent steps follow: a) deposition of a barrier layer (e.g., ALD or PVD of tantalum nitride); b) punch-thru step; c) deposition of ruthenium layer by ALD or PVD; d) deposition of seed copper by electroless, ECP or PVD; and e) deposition of bulk copper by electroless or ECP.

### Example 4

The subsequent steps follow: a) deposition of ruthenium layer by ALD or PVD; b) punch-thru step; c) deposition of ruthenium layer by ALD or PVD; d) deposition of seed copper by electroless, ECP or PVD; and e) deposition of bulk copper by electroless or ECP.

### Example 5

The subsequent steps follow: a) deposition of ruthenium layer by ALD or PVD; b) punch-thru step; c) deposition of ruthenium layer by ALD or PVD; and d) deposition of copper by electroless or ECP.

### Example 6

The subsequent steps follow: a) pre-clean of the substrate; b) deposition of ruthenium layer by ALD or PVD; c) deposition of seed copper by electroless, ECP or PVD; and d) deposition of bulk copper by electroless or ECP.

### Example 7

The subsequent steps follow: a) deposition of a barrier layer (e.g., ALD or PVD of tantalum nitride); b) deposition of ruthenium layer by ALD or PVD; c) punch-thru step; d) deposition of ruthenium layer by ALD or PVD; e) deposition of seed copper by electroless, ECP or PVD; and f) deposition of bulk copper by electroless or ECP.

### Example 8

The subsequent steps follow: a) deposition of a barrier layer (e.g., ALD or PVD of tantalum nitride); b) punch-thru step; c) deposition of a barrier layer (e.g., ALD or PVD of tantalum nitride); d) deposition of ruthenium layer by ALD or PVD; d) deposition of seed copper by electroless, ECP or PVD; and e) deposition of bulk copper by electroless or ECP.

### Example 9

The subsequent steps follow: a) pre-clean of the substrate; b) deposition of a barrier layer (e.g., ALD or PVD of tantalum nitride); c) deposition of ruthenium layer by ALD or PVD; and d) deposition of copper bulk by electroless or ECP.

### Example 10

The subsequent steps follow: a) deposition of a tantalum nitride barrier layer by ALD; b) deposition of ruthenium layer by ALD; c) optionally exposure of substrate to a thermal annealing process; d) deposition of seed copper by electroless; and e) deposition of bulk copper by electroless.

### Example 11

The subsequent steps follow: a) deposition of a tantalum nitride barrier layer by PVD; b) deposition of ruthenium layer by ALD; c) optionally exposure of substrate to a thermal annealing process; d) deposition of seed copper by PVD; and e) deposition of bulk copper by electroless.

### Example 12

The subsequent steps follow: a) deposition of a tantalum nitride barrier layer by PVD; b) deposition of ruthenium layer by PVD; c) optionally exposure of substrate to a thermal annealing process; d) deposition of seed copper by PVD; and e) deposition of bulk copper by electroless.

### Example 13

The subsequent steps follow: a) deposition of a tantalum nitride barrier layer by PVD; b) deposition of ruthenium layer by PVD; c) optionally exposure of substrate to a thermal annealing process; d) deposition of seed copper by electroless; and e) deposition of bulk copper by electroless.

### Example 14

The subsequent steps follow: a) deposition of a tantalum nitride barrier layer by ALD; b) deposition of ruthenium layer by ALD; c) optionally exposure of substrate to a thermal annealing process; and d) deposition of bulk copper by electroless.

### Example 15

The subsequent steps follow: a) deposition of a tantalum nitride barrier layer by PVD; b) deposition of ruthenium layer by ALD; c) optionally exposure of substrate to a thermal annealing process; and d) deposition of bulk copper by electroless.

### Example 16

The subsequent steps follow: a) deposition of a tantalum nitride barrier layer by ALD; b) deposition of ruthenium layer by PVD; c) optionally exposure of substrate to a thermal annealing process; and d) deposition of bulk copper by electroless.

### Example 17

The subsequent steps follow: a) deposition of a tantalum nitride barrier layer by PVD; b) deposition of ruthenium layer by PVD; c) optionally exposure of substrate to a thermal annealing process; and d) deposition of bulk copper by electroless.

The pre-clean steps include methods to clean or purify aperture 110, such as the removal of residue at the bottom of aperture 110 (e.g., carbon) or chemical reduction of ruthenium oxide to ruthenium metal. The punch-thru steps include a method to remove material (e.g., barrier layer 106) from the bottom of aperture 110 to expose metal contact 104. Further disclosure of punch-thru steps is described in more detail in the commonly assigned U.S. Pat. No. 6,498,091, which is incorporated herein in its entirety by reference. The punch-thru steps may be conducted within a process chamber, such as either a deposition chamber or a clean chamber. In embodiments of the invention, clean steps and punch-thru steps may be applied to ruthenium layer 108 and barrier layer 106. Further disclosure of the integrated methods are described in more detail in the commonly assigned and co-pending U.S. Ser. No. 10/865,042, entitled “Integration of ALD Tantalum Nitride for Copper Metallization,” filed Jun. 10, 2004, and published as US 2005-0106865, which is incorporated herein in its entirety by reference.

A “substrate surface,” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, alloys, and other conductive materials, depending on the application. Barrier layers, metals or metal nitrides on a substrate surface include titanium, titanium nitride, tungsten nitride, tantalum and tantalum nitride. Substrates may have various dimensions, such as 200 mm or 300 mm diameter wafers, as well as, rectangular or square panes. Unless otherwise noted, embodiments and examples described herein are preferably conducted on substrates with a 200 mm diameter or a 300 mm diameter, more preferably, a 300 mm diameter. Processes of the embodiments described herein deposit tantalum, tantalum nitride, copper and ruthenium materials on a variety of substrates and surfaces. Substrates on which embodiments of the invention may be useful include, but are not limited to semiconductor wafers, such as crystalline silicon (e.g., Si<100> or Si<111>), silicon oxide, strained silicon, silicon germanium, doped or undoped polysilicon, doped or undoped silicon wafers and patterned or non-patterned wafers. Substrates may be exposed to a pretreatment process to polish, etch, reduce, oxidize, hydroxylate, anneal and/or bake the substrate surface.

While foregoing is directed to the preferred embodiment of the invention, other and further embodiments of the invention may be devised without departing from the basic scope thereof, and the scope thereof is determined by the claims that follow.

1. A method for forming a copper-containing material on a substrate, comprising:
forming a barrier layer on a substrate;
forming a ruthenium material on the barrier layer; and
exposing the substrate to an electroless copper solution containing an inhibitor source to form a copper material on the ruthenium material.

2. The method of claim 1, wherein the copper material is deposited as a seed layer and a bulk layer is deposited thereon.

3. The method of claim 2, wherein the bulk layer comprises copper and is formed by an electroless deposition process or an electrochemical plating process.

4. The method of claim 1, wherein the copper material is deposited as a bulk layer.

5. The method of claim 4, wherein at least one aperture on the substrate is filled free or substantially free of voids and seams within the copper material.

6. The method of claim 5, wherein a field across the substrate is maintained free or substantially free of the copper material while exposing the substrate to the electroless copper solution.

7. The method of claim 1, wherein the barrier layer contains a barrier material selected from the group consisting of tantalum, tantalum nitride, tantalum silicon nitride, titanium, titanium nitride, titanium silicon nitride, tungsten nitride, alloys thereof, derivatives thereof and combinations thereof.

8. The method of claim 7, wherein the barrier layer contains a tantalum nitride material deposited to a thickness of about 20 Å or less by an atomic layer deposition process or a physical vapor deposition process.

9. The method of claim 8, wherein the ruthenium material is deposited to a thickness of about 20 Å or less by an atomic layer deposition process or a physical vapor deposition process.

10. The method of claim 9, wherein the substrate is exposed to an annealing process after forming the ruthenium material and prior to forming the copper material.

11. The method of claim 1, wherein the electroless copper solution, comprises:
a copper source at a concentration within a range from about 10 mM to about 40 mM;
an EDTA source at a concentration within a range from about 75 mM to about 400 mM;
a glyoxylic acid source at a concentration within a range from about 100 mM to about 400 mM;
a surfactant source at a concentration of about 1,000 ppm or less;
a dipyridyl source at a concentration within a range from about 10 ppm to about 100 ppm; and
a pH adjusting agent at a concentration to provide a pH value of at least about 11.

12. The method of claim 11, further comprising:
the copper source at a concentration of about 26 mM;
the EDTA source at a concentration of about 205 mM;
the glyoxylic acid source at a concentration of about 217 mM;
a PEG source at a concentration of about 0.5 g/L;
the dipyridyl source at a concentration of about 25 ppm; and
the pH adjusting agent at a concentration to provide a pH value of at least about 12.

13. The method of claim 11, wherein the electroless copper solution is formed by an in-line mixing process and is exposed at a point-of-use to the substrate.

14. The method of claim 13, wherein a copper concentrate solution, a reductant concentrate solution and water are combined during the in-line mixing process.

15. The method of claim 14, wherein the copper concentrate solution and the reductant concentrate solution each contain equal or substantially equal concentrations of a complexing agent.

16. The method of claim 1, wherein the electroless copper solution, comprises:
a copper source at a concentration within a range from about 10 mM to about 40 mM;
a complexing agent source at a concentration within a range from about 75 mM to about 400 mM;
a reductant source at a concentration within a range from about 100 mM to about 400 mM;
the inhibitor source at a concentration within a range from about 10 ppm to about 100 ppm; and
a pH adjusting agent at a concentration to provide a pH value of at least about 10.

17. A method for forming a copper-containing material on a substrate, comprising:
depositing a ruthenium tantalum alloy on a substrate during a first deposition process; and
exposing the substrate to an electroless copper solution to form a copper material on the ruthenium tantalum alloy.

18. The method of claim 17, wherein the ruthenium tantalum alloy is deposited by a physical vapor deposition process and contains about 50 wt % ruthenium and about 50 wt % tantalum.

19. The method of claim 18, wherein the ruthenium tantalum alloy is deposited to a thickness of about 20 Å or less.

20. The method of claim 17, wherein the copper material is deposited as a seed layer and a bulk layer is deposited thereon.

21. The method of claim 20, wherein the bulk layer comprises copper and is formed by an electroless deposition process or an electrochemical plating process.

22. The method of claim 17, wherein the copper material is deposited as a bulk layer.

23. The method of claim 22, wherein at least one aperture on the substrate is filled free or substantially free of voids and seams within the copper material.

24. The method of claim 23, wherein a field across the substrate is free or substantially free of the copper material, while forming the copper material during an electroless deposition process.

25. The method of claim 17, wherein the electroless copper solution, comprises:
a copper source at a concentration within a range from about 10 mM to about 40 mM;
an EDTA source at a concentration within a range from about 75 mM to about 400 mM;
a glyoxylic acid source at a concentration within a range from about 100 mM to about 400 mM;
a surfactant source at a concentration of about 1,000 ppm or less;
an inhibitor source at a concentration within a range from about 10 ppm to about 100 ppm; and
a pH adjusting agent at a concentration to provide a pH value of at least about 11.

26. The method of claim 25, further comprising:
the copper source at a concentration of about 26 mM;
the EDTA source at a concentration of about 205 mM;
the glyoxylic acid source at a concentration of about 217 mM;
a PEG source at a concentration of about 0.5 g/L;
a dipyridyl source at a concentration of about 25 ppm; and
the pH adjusting agent at a concentration to provide a pH value of at least about 12.

27. The method of claim 25, wherein the electroless copper solution is formed by an in-line mixing process and is exposed at a point-of-use to the substrate.

28. The method of claim 27, wherein a copper concentrate solution, a reductant concentrate solution and water are combined during the in-line mixing process.

29. The method of claim 28, wherein the copper concentrate solution and the reductant concentrate solution each contain equal or substantially equal concentrations of a complexing agent.

30. The method of claim 17, wherein the electroless copper solution, comprises:
a copper source at a concentration within a range from about 10 mM to about 40 mM;
a complexing agent source at a concentration within a range from about 75 mM to about 400 mM;
a reductant source at a concentration within a range from about 100 mM to about 400 mM;
an inhibitor source at a concentration within a range from about 10 ppm to about 100 ppm; and
a pH adjusting agent at a concentration to provide a pH value of at least about 10.

31. A method for forming a copper-containing material on a substrate, comprising:
forming a barrier layer on a substrate having at least one aperture;
forming a ruthenium material on the barrier layer; and
filling the at least one aperture free or substantially free of voids and seams with a copper material during an electroless deposition process.

32. The method of claim 31, wherein the copper material is formed from an electroless copper solution containing an inhibitor source during the electroless deposition process.

33. The method of claim 31, wherein a copper seed layer is deposited on the ruthenium material prior to filling the at least one aperture.

34. The method of claim 33, wherein the copper seed layer is deposited by a copper electroless deposition process or a physical vapor deposition process.

35. The method of claim 31, wherein a field across the substrate is free or substantially free of the copper material during the electroless deposition process.

36. The method of claim 31, wherein the barrier layer contains a barrier material selected from the group consisting of tantalum, tantalum nitride, tantalum silicon nitride, titanium, titanium nitride, titanium silicon nitride, tungsten nitride, alloys thereof, derivatives thereof and combinations thereof.

37. The method of claim 36, wherein the barrier layer contains a tantalum nitride material deposited to a thickness of about 20 Å or less by an atomic layer deposition process or a physical vapor deposition process.

38. The method of claim 37, wherein the ruthenium material is deposited to a thickness of about 20 Å or less by an atomic layer deposition process or a physical vapor deposition process.

39. The method of claim 38, wherein the substrate is exposed to an annealing process after forming the ruthenium material and prior to forming the copper material.

40. The method of claim 31, wherein the electroless deposition process includes exposing the substrate to an electroless copper solution, comprising:
a copper source at a concentration within a range from about 10 mM to about 40 mM;
an EDTA source at a concentration within a range from about 75 mM to about 400 mM;
a glyoxylic acid source at a concentration within a range from about 100 mM to about 400 mM;
a surfactant source at a concentration of about 1,000 ppm or less;
an inhibitor source at a concentration within a range from about 10 ppm to about 100 ppm; and
a pH adjusting agent at a concentration to provide a pH value of at least about 11.

41. The method of claim 40, further comprising:
the copper source at a concentration of about 26 mM;
the EDTA source at a concentration of about 205 mM;
the glyoxylic acid source at a concentration of about 217 mM;
a PEG source at a concentration of about 0.5 g/L;
a dipyridyl source at a concentration of about 25 ppm; and
the pH adjusting agent at a concentration to provide a pH value of at least about 12.

42. The method of claim 40, wherein the electroless copper solution is formed by an in-line mixing process and is exposed at a point-of-use to the substrate.

43. The method of claim 42, wherein a copper concentrate solution, a reductant concentrate solution and water are combined during the in-line mixing process.

44. The method of claim 43, wherein the copper concentrate solution and the reductant concentrate solution each contain equal or substantially equal concentrations of a complexing agent.

45. The method of claim 31, wherein the electroless deposition process includes exposing the substrate to an electroless copper solution, comprising:
a copper source at a concentration within a range from about 10 mM to about 40 mM;
a complexing agent source at a concentration within a range from about 75 mM to about 400 mM;
a reductant source at a concentration within a range from about 100 mM to about 400 mM;
an inhibitor source at a concentration within a range from about 10 ppm to about 100 ppm; and
a pH adjusting agent at a concentration to provide a pH value of at least about 10.

46. A method for forming a copper-containing material on a substrate, comprising:
forming a barrier layer on a substrate during a first atomic layer deposition process or a physical vapor deposition process;
forming a ruthenium layer having a thickness of about 20 Å or less on the barrier layer during a second atomic layer deposition process; and
exposing the substrate to an electroless copper solution containing an inhibitor source to form a copper material on the ruthenium layer.

47. A method for forming a copper-containing material on a substrate, comprising:
depositing a ruthenium material on a barrier layer disposed on a substrate;
combining at least a copper concentrate solution and water by an in-line mixing step to form an electroless copper solution; and
exposing the substrate to the electroless copper solution to form a copper material on the ruthenium material.

48. The method of claim 47, wherein a reductant concentrate solution is also combined with the copper concentrate solution and the water during the in-line mixing step.

49. The method of claim 48, wherein the copper concentrate solution and the reductant concentrate solution each contain equal or substantially equal concentrations of a complexing agent.

50. The method of claim 47, wherein the electroless copper solution, comprises:
a copper source at a concentration within a range from about 10 mM to about 40 mM;
an EDTA source at a concentration within a range from about 75 mM to about 400 mM;
a glyoxylic acid source at a concentration within a range from about 100 mM to about 400 mM;
a surfactant source at a concentration of about 1,000 ppm or less;
an inhibitor source at a concentration within a range from about 10 ppm to about 100 ppm; and
a pH adjusting agent at a concentration to provide a pH value of at least about 11.
